(19) United States
(12) Patent Application Publication
(10) Pub. No.: US 2007/0074902 A1
(43) Pub. Date: Apr. 5, 2007

(54) Printed-wiring board, multilayer printed-wiring board and manufacturing process therefor

(75) Inventor: Eiji Hirata, Isesaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: CMK CORPORATION, Shinjuku-ku (JP)

(21) Appl. No.: 11/452,321

(22) Filed: Jun. 14, 2006

(30) Foreign Application Priority Data
Oct. 3, 2005 (JP) 2005-290122
Mar. 29, 2006 (JP) 2006-91241

(51) Int. Cl. H05K 1/11; H01K 3/10

(52) U.S. Cl. 174/262; 29/847; 29/852; 174/250

(57) ABSTRACT

The present invention provides a printed-wiring board which can make the electric wiring densified and can be thinned, even when having a BVH of a non-penetration hole filled with a selectively plating, formed therein for interfacial connection means. The printed-wiring board has a blind via hole connecting different wiring-pattern-formed layers with each other, wherein the blind via hole is a non-penetration hole filled with a plating, and the plating is not formed on a wiring pattern including the round of the blind via hole. The process for manufacturing the printed-wiring board having a blind via hole connecting different wiring-pattern-formed layers with each other includes the steps of: sequentially layering at least a metallic foil and a barrier metal layer to be differently etched from the metallic foil, on an insulation layer; preparing such a non-penetration hole as to reach a desired wiring-pattern-forming layer, by directly irradiating the barrier metal layer with a laser beam; cleaning the inside of the non-penetration hole by desmearing treatment; filling the non-penetration hole with a plating, and at the same time forming a plating on the barrier metal layer, by plating treatment; removing the plating which has been formed on the barrier metal layer and protrudes from the non-penetration hole, by etching treatment; peeling the barrier metal layer; and etching the metallic foil to form a wiring pattern.

### BACKGROUND OF THE INVENTION

1. Field of the Invention

The present invention relates to a printed-wiring board provided with a blind via hole, a multilayer printed-wiring board and a manufacturing process therefor, and particularly to a printed-wiring board which makes the electric wiring densified and is thinned, the multilayer printed-wiring board and the manufacturing process therefor.

2. Description of the Related Art

With the densification and miniaturization of an electronic product, multi-layering has proceeded in all fields including a semiconductor package substrate, a module substrate and a mother board substrate, and connecting means for connecting different wiring-pattern-formed layers with each other has been changing from a form using a penetration through hole which penetrates from one side to the other side of the printed-wiring board, to a form using a stacked via hole with such a structure that several interstitial via holes (hereafter described as “IVH”, in which particularly the hole for connecting layers with each other through a plated metal is called a blind via hole and described as “BVH”) for connecting desired wiring-pattern-formed layers with each other are layered so as to form a coax.

The stacked via hole and a fully stacked via hole with such a structure that IVHs are layered on a coax of all layers have been realized by a conventional subtractive process (which is a process for forming a wiring pattern through forming an etching resist pattern on a metal such as a copper foil, and etching a metal exposed out of the etching resist pattern).

However, a conventional subtractive process could not cope with a request for micro wiring.

Specifically, the subtractive process can form a micro wiring circuit on a single-sided printed-wiring board because it has only to etch a previously layered copper foil in forming it, but has a disadvantage in forming the micro wiring circuit on a printed-wiring board with two or more layers to be patterned, because the process needs to electroless-plate and electrolytically plate the whole insulation substrate with a metal in a step of forming a through hole or a BVH, consequently has to etch a conductor consisting of “a copper foil+a plating”, as a result, increases a thickness of a conductor and the thickness of the conductor varies depending on the position, because a plating essentially has a wide range of thickness distribution.

For information, the minimum wiring pattern width L/wiring pattern spacing S (hereafter described as L/S) capable of stably being formed with a conventional subtractive process was 75 μm/75 μm.

In such a technical background, a semi-additive process has been suitable for coping with micro wiring.

A semi-additive process is the one which forms a wiring pattern by forming a plated resist with an opposite pattern to a wiring pattern to be provided, and by depositing a metal on a part having no plated resist formed thereon, can deposit copper even in a narrow area of the part having no plated resist formed thereon, as far as a plating liquid can enter there, and accordingly can form the pattern with the L/S of about as small as 25 μm/25 μm.

However, a semi-additive process could not form a fully stacked via hole which has the IVHs of all layers layered on a coax, even though it could form IVHs in the all layers.

This is because when a double-sided core substrate is formed with a semi-additive process, the substrate can not have a non-penetration hole structure as interfacial connection means, and consequently needs to make a penetration through hole connect layers with each other, and so that the process can not form a BVH on it, which is a non-penetration hole filled with a plating, and is the condition necessary to form a stacked via hole.

Specifically, the semi-additive process can form a BVH which is a non-penetration hole filled with a plating, to form a multi-layered wiring board, because the wiring board has the layers built up on the both sides of the double-sided core substrate, and enables a non-penetration hole to be formed in the built up layers. Accordingly, the semi-additive process can form a stacked via hole in the built up layer, but can not form a fully stacked via hole in the double-sided core substrate, because it can not form a BVH filled with a plating (which means that the semi-additive process can not sufficiently form high-density wiring because it can not form BVHs of all layers on a coax).

The semi-additive process has further demerits as described below.

At first, because a semi-additive process is the one which selectively deposits a metal in a wiring-pattern-forming part by forming an electroless-plating on an insulation layer, and then electrolytically plating a metal on the electroless-plated layer while using it as a feeding layer, it can hardly provide the adherence of a wiring pattern to an insulation layer (and the adherence to a resin which will be sealed after an IC chip is mounted thereon), without an aid of an anchoring effect obtained through roughening the insulation layer.

In order to form a roughened surface with various sizes of recesses or bumps for obtaining such an anchoring effect, an insulation material needs to be prepared while considering a cross-linking density of a resin, and a filler in the resin or a filler desorption system (for forming unevenness) by using a desmearing step, which leads to the lowering of the chemical resistance of a cured material as a whole, and limits a base resin, a curing agent and the filler to be used in the insulation material, and could not sufficiently cope with the various requirements (i.e., certain electric properties such as insulation properties and dielectric properties, moisture absorption characteristics, rigidity and flexibility are required).

In addition, because a wiring pattern is unevenly formed on a substrate surface, which occurs according to the design of a printed-wiring board, such an additive process as to form a wiring pattern with selective plating tends to form a thick plating at a part in which the wiring pattern is rough, due to the concentration of an electric current and to form a thin plating at a part in which the wiring pattern is dense, so that the formed printed-wiring board can not occasionally match the impedance.

On the other hand, a printed-wiring board for coping with micro wiring, IVHs in all layers and fully stacked via holes with an unprecedented method has been also suggested (for instance, see Patent Documents 1, 2 and 3).

Printed-wiring boards disclosed in Patent Documents 1 and 2 have the configuration of connecting wiring-pattern-formed layers with each other through a conductive paste and can form IVHs in all layers and fully stacked via holes.

However, each of the printed-wiring boards connects a wiring pattern made of a copper foil and another layer with a conductive paste, so that the copper foil needs to have a slightly-bigger anchor (a metallic bump) thereon, for the purpose of decreasing a conduction resistance and improving connection reliability. Thus, each of the printed-wiring boards is advantageous for micro wiring from the viewpoint of a thickness tolerance of a conductor (because the circuit is formed by etching only a previously layered copper foil), but tends to cause copper remaining due to the anchor, and as a result could not form the micro wiring.

Each of the printed-wiring boards also has not suited for high-density electric wiring which is required to form IVHs with a small diameter, because it employs a conductive paste for interfacial connection means, which makes conduction resistance in IVH extremely higher than that in a copper-plating. Furthermore, the paste has inferior hole-filling properties to a plating liquid due to a large difference between the viscosities of them, and could not give the printed-wiring board an IVH with a sufficiently small diameter after the conductive paste has been printed.

A printed-wiring board in Patent Document 3 has a configuration capable of forming micro wiring, IVHs in all layers and a fully stacked via hole, but hardly gives the printed-wiring board an IVH with a sufficiently small diameter after the conductive paste has been printed, similarly to those in the above described Patent Documents 1 and 2, because the printed-wiring board uses an interfacial connection bump formed by etching a thick copper foil as an IVH.

The printed-wiring board also has a problem that bonding between a copper foil and an interfacial connection bump is not reliable, because they are thermo-compression-bonded with the use of a high polymer material such as epoxy, while being heated at such a temperature as not to carbonize the material, but still the pressure is not sufficient because of being dispersed at high-density areas of bumps (IVHS) for interfacial connection, which are unevenly distributed within a substrate surface.

Furthermore, the printed-wiring board uses an IVH made of a bump formed by etching a thick copper foil, for interfacial connection, as a result, can decrease electric resistance between layers in comparison with an IVH made of a filled conductive paste, but still can not sufficiently decrease the electric resistance because of the absolute presence of nickel between the bump for interfacial connection and a wiring pattern, and besides, because nickel has different linear expansion coefficient and elastic modulus in a direction perpendicular to a crystal orientation (a face direction) from those of copper, can not obtain sufficient adherence when having received thermal shock compared to connection between the copper foil and a copper-plating.

On the other hand, the present applicant has already filed a patent for a process for manufacturing a printed-wiring board (see Patent Document 4), which forms a circuit through etching only a copper foil, by forming a plating selectively on a part at which a BVH will be formed when forming the BVH. The manufacturing process will be briefly described with reference to FIG. 10.

FIG. 10 shows an instance of forming a built up electric wiring layer on an internal layer core substrate which is not shown in a diagram, by the steps of: at first, as shown in FIG. 10(a), sequentially layering an insulation layer 1 and a metallic foil 2 such as a copper foil, on the formed layer of a via bottom round 8b formed on the internal layer (for instance, layering a copper foil with a resin layer); and subsequently preparing such a non-penetration hole 5 as to reach the via bottom round 8b by irradiation with a laser beam (see FIG. 10(b)).

Subsequently, the non-penetration-hole 5 is desmeared, and then, as shown in FIG. 5(c), a layer 3 made of a barrier metal (for instance, Ni—B and Ni—P) is formed on the surface of a via bottom round 8b which is exposed from the non-penetration-hole 5 and the outer surface of a metallic foil 2, by using a displacement electroless plating technique.

Subsequently, an electroless-plated layer (for instance, an electroless-copper-plated layer), which is not shown in a diagram, is formed on the whole external layer surface including a non-penetration hole 5, and then a plated layer 7 is filled in the non-penetration-hole 5 and at the same time is formed on the external layer (see FIG. 10(d)), with an electrolytic plating technique (for instance, an electrolytic copper plating technique with the use of a plating liquid for a filling via).

Next, as shown in FIG. 10(e), a pattern is formed on a blind via hole 9 and a round part of it (hereafter called “a plated round 8a”); then, as shown in FIG. 10(f), a barrier metal layer 3 exposed to an external layer is removed by etching; and subsequently, a circuit is formed in the exposed metallic foil 2 to provide a printed-wiring board Pb of FIG. 10(g), which has a wiring pattern 8 in the external layer including a metallic foil round 2a.

Thus formed printed-wiring board has an IVH made of a BVH which is a non-penetration hole filled with a plating, consequently can decrease the diameter of the IVH (or equivalently, the diameter of the BVH), and can form a stacked via hole or a fully stacked via hole when preparing a multi-layered wiring board. In addition, a copper foil can reduce a thickness tolerance to one-tenth or lower of that of a copper film plated on a substrate, due to a manufacturing process, and accordingly can easily form a micro wiring pattern (equivalent to a wiring pattern 8 in the drawing).

However, the above described manufacturing process leaves a plated round 8a on the round of the BVH (equivalent to “a metallic foil round 2a” shown in FIG. 10(g)), which has been plated when forming the BVH; must increase the thickness of an inter-level isolation layer by the thickness of the plating when forming a multi-layered wiring board (because specific thickness becomes necessary as the thickness of the insulation layer between wiring patterns of a top layer and a bottom layer, in order to secure insulation performance between the wiring patterns in the top layer and the bottom layer); and can not thin a finally provided multilayer printed-wiring board.

In addition, the manufacturing process forms a plating selectively in a non-penetration hole and on the round, and for the reason, increases a final diameter of the round (the diameter of a metallic foil round 2a), which has disturbed the densification of electric wiring.

[Patent Document 1] JP-A-5-77840

[Patent Document 2] JP-A-6-342977

[Patent Document 3] JP-A-2002-43506

[Patent Document 4] JP-A-2004-319994

### SUMMARY OF THE INVENTION

The present invention is designed for solving the above described problems; and the object is to provide a printed-wiring board and a multilayer printed-wiring board, which can make the electric wiring densified and can be thinned, even when having a BVH of a non-penetration hole filled with a selectively plating, formed therein for interfacial connection means, and to provide a manufacturing process therefor.

The present invention according to claim 1 is a printed-wiring board which is directed at achieving the above described object, and has a blind via hole connecting different wiring-pattern-formed layers with each other, wherein the blind via hole is a non-penetration hole filled with a plating, and the plating is not formed on a wiring pattern including the round of the blind via hole.

As described above, the printed-wiring board has such a configuration as not to have a plating (a plated round) formed on a round of a blind via hole, and accordingly can form a round (a metallic foil round) without needing to consider matching tolerance when forming the plated round. Accordingly, the printed-wiring board allows the diameter of the round to be smaller than ever, and as a result, allows electric wiring to be further densified.

The present invention according to claim 2 provides the printed-wiring board as described above, wherien the wiring pattern including the round of the blind via hole is placed so that the surface of the wiring pattern is in the same plane as an insulation layer.

As a result of this, the electric wiring can be densified and at the same time, can be thinned.

The present invention according to claim 3 provides the printed-wiring board wherein all wiring patterns including the blind via hole are made from copper.

As a result of this, conduction resistance can be lowered.

The present invention according to claim 4 provides the printed-wiring board, wherein the blind via hole is the non-penetration hole filled with a film plated in a state of leaving a metallic umbrella which protrudes at the edge of the opening of the non-penetration hole and is formed when the non-penetration hole for forming the blind via hole has been prepared.

Thereby, the blind via hole can reliably connects layers with each other.

The present invention according to claim 5 provides the printed-wiring board, wherein the plating is filled so that the upper surface of the plating can be approximately in the same plane as the round of a blind via hole.

Thereby, the printed-wiring board can acquire a flat surface even when multi-layered.

The present invention according to claim 6 provides a multilayer printed-wiring board comprising a plurality of the printed-wiring boards, to achieve the above described object.

Thereby, the multilayer printed-wiring board can be thinned because printed-wiring boards having no plated round formed on the upper part of a blind via hole are multi-layered.

The present invention according to claim 7 provides a process for manufacturing a printed-wiring board having a blind via hole connecting different wiring-pattern-formed layers with each other to achieve the above described object, which comprises the steps of: sequentially layering at least a metallic foil and a barrier metal layer to be differently etched from the metallic foil, on an insulation layer; preparing such a non-penetration hole as to reach a desired wiring-pattern-forming layer, by directly irradiating the barrier metal layer with a laser beam; cleaning the inside of the non-penetration hole by desmearing treatment; filling the non-penetration hole with a plating, and at the same time forming a plating on the barrier metal layer, by plating treatment; removing the plating which has been formed on the barrier metal layer and protrudes from the non-penetration hole, by etching treatment; peeling the barrier metal layer; and etching the metallic foil to form a wiring pattern.

Thereby, a printed-wiring board having electric wiring thereon densified can be easily obtained.

The present invention according to claim 8 provides a process for manufacturing the printed-wiring board, wherein the invention of claim 7 is treated in the following manner; the non-penetration hole is prepared by irradiation with the laser beam of carbon dioxide gas, and is plated in a state of leaving a metallic umbrella which has been formed at the edge of the opening of the non-penetration hole by irradiation with the laser beam of carbon dioxide gas.

Thereby, a printed-wiring board having a blind via hole with high connection reliability can be easily obtained.

The present invention according to claim 9 provides a process for manufacturing a multilayer printed-wiring board, which is directed at achieving the above described object, and includes repeating the steps according to claim 7 or 8.

Thereby, a thinned multilayer printed-wiring board can be easily obtained.

The presnet invention according to claim 10 provides a process for manufacturing a printed-wiring board having a blind via hole connecting different wiring-pattern-formed layers with each other to achieve the above described object, which comprises the steps of: forming a wiring pattern having the round of a bling via hole; placing the wiring pattern in such a way that it is in the same plane as an insulation layer; preparing such a non-penetration hole as to reach a desired wiring-pattern-forming layer, by irradiating the round opening-hole of the blind via hole with a laser beam; cleaning the inside of the non-penetration hole by desmearing treatment; filling the non-penetration hole with a plating, and at the same time forming a plating on the outer layer, by plating under such a condition that a barrier metal layer having an etching condition diffrenent from that of the wiring pattern is placed on the part of the surface of the wiring pattern uncovered by an insulation layer; and removing by etching the plating on the outer layer; peeling the barrier metal layer.

Thereby, the electric wiring can be densified and at the same time, can be thinned.

The present invention according to claim 11 provides a process for manufacturing a multilayer printed-wiring board, which is directed at achieving the above described object, wherein the invention accordin to claim 10 is treated in the following manner; the non-penetration hole is prepared by irradiation with the laser beam of carbon dioxide gas, and is plated in a state of leaving a metallic umbrella which has been formed at the edge of the opening of the non-penetration hole by irradiation with the laser beam of carbon dioxide gas.

Thereby, a thinned printed-wiring board having a blind via hole with high connection reliability can be easily obtained.

The present invention according to claim 12 provides a process for manufacturing a multilayer printed-wiring board, including repeating the steps according to claim 10 or 11.

Thereby, a further thinned multilayer printed-wiring board can be easily obtained.

### BRIEF DESCRIPTION OF THE DRAWINGS

FIG. 1 is a cross-section diagrammatic drawing for explaining a process of manufacturing a printed-wiring board according to the present invention;

FIG. 2 is a cross-section diagrammatic drawing for explaining a relationship between a metallic umbrella and a plating;

FIG. 3 is a cross-section diagrammatic drawing for explaining a multilayer printed-wiring board according to the present invention;

FIG. 4 is a cross-section diagrammatic drawing for explaining an example having no metallic umbrella formed therein;

FIG. 5 is a cross-section diagrammatic drawing for explaining another process for manufacturing a printed-wiring board according to the present invention;

FIG. 6 is a cross-section diagrammatic drawing, in addition to FIG. 5, for explaining another process of manufacturing a printed-wiring board according to the present invention;

FIG. 7 is another cross-section diagrammatic drawing for explaining a multilayer printed-wiring board according to the present invention;

FIG. 8 is another cross-section diagrammatic drawing for explaining an example having no metallic umbrella formed therein;

FIG. 9 a cross-section diagrammatic drawing for explaining the condition in which the wiring-pattern formed by etching is placed in an insulation layer;

FIG. 10 is a cross-section diagrammatic drawing for explaining a process for manufacturing a conventional printed-wiring board.

### DESCRIPTION OF THE SYMBOLS

1: insulation layer

2: metallic foil

2a: metallic foil round

2b: opening hole

3: barrier metallic layer

4: double-sided, metallic foil-laminated plate

5: non-penetration hole

6: metallic umbrella

7: metallic coating

8: wiring pattern

8a: metallic-plated round

8b: via bottom round

9: BVH

10: a part having no barrier metal layer formed thereon

11: carrier

11a, 11b: basic carrier plate

P, Pb: printed wiring board

S: surface of a metallic foil round

B: back side of a metallic foil round

L1: diameter of a metallic foil round

L2: diameter of an opening hole

### BEST MODE FOR CARRYING OUT THE INVENTION

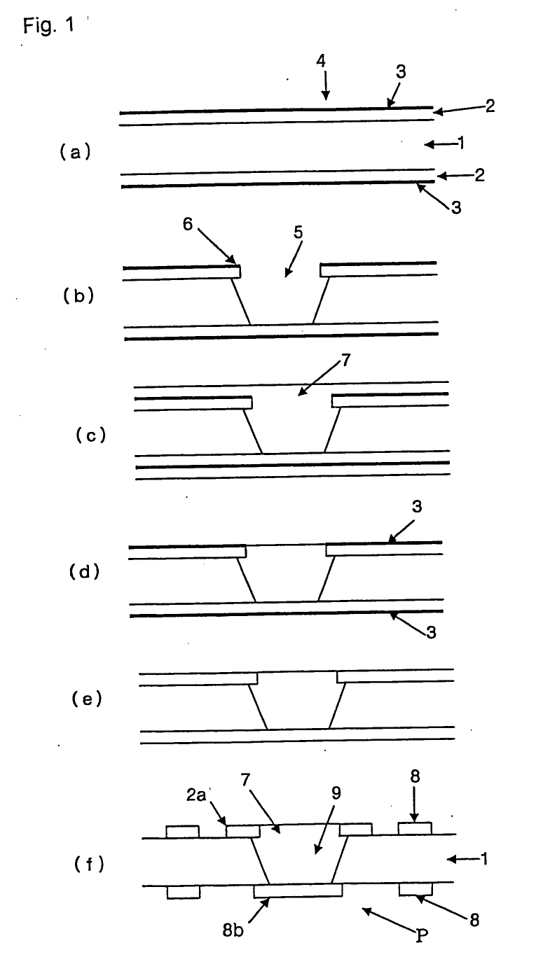

An embodiment of a printed-wiring board according to the present invention will be now described with reference to FIG. 1(f).

FIG. 1(f) shows a diagrammatic cross-section explanatory drawing of a double-sided printed-wiring board P having a wiring pattern 8 formed on both sides of an insulation layer 1. The double-sided printed-wiring board has a configuration consisting of: the wiring pattern 8 formed on both sides of the insulation layer 1; a via bottom round 8b formed on one surface of the insulation layer 1; a metallic foil round 2a formed on the other surface; a BVH 9 of a non-penetration hole 5 filled with a plating 7; and a wiring pattern 8 including the metallic foil round 2a, on which the plating 7 is not formed: and allows a diameter of the metallic foil round 2a to be decreased, and electric wiring to be densified.

Subsequently, a process for manufacturing such a printed-wiring board P in FIG. 1(f) will be now described.

At first, as shown in FIG. 1(a), a double-sided metallic-foil-plated laminate 4 is prepared which has a structure formed by sequentially laminating a metallic foil 2 (for instance, a copper foil) and a barrier metal layer 3 of which the rate to be etched is different from that of the metallic foil 2, on both sides of an insulation layer 1; and subsequently, such a non-penetration hole 5 as to reach one metallic foil 2 is prepared by irradiation with a laser beam (see FIG. 1(b)).

Here, the barrier metal layer 3 may be any metal as far as it protects a metallic foil 2 from being etched when a plating 7 to be later formed on the barrier metal layer 3 will be removed by etching; and includes, for instance, Ni, Sn and Ag.

In addition, the laser beam may be any laser beam as far as it forms a hole in a barrier metal layer 3 when directly irradiates the layer, but is preferably the laser of carbon dioxide gas from the viewpoint of a cost and the necessity of forming a metallic umbrella 6 on the edge of the opening after the hole has been prepared.

Next, a non-penetration hole 5 is desmeared in a state of leaving a metallic umbrella 6 formed on the edge of the opening; then an electroless-plating (for instance, an electroless-copper-plating), which is not shown in the diagram, is formed on the whole surface; and subsequently a plating 7 is formed so as to fill the inside of the non-penetration hole 5 and is formed also on an external layer (see FIG. 1(c)) by electrolytic plating treatment (such as electrolytic copper plating treatment with the use of a plating liquid for filling a via hole).

Next, a barrier metal layer 3 is exposed (see FIG. 1(d)) by etching a plating 7 (by alkaline etching treatment), which is exposed outside.

Here, a metallic umbrella 6 formed on the edge of the opening of a non-penetration hole 5 is not always necessary, but it is preferable to leave the metallic umbrella 6 in order to secure connection reliability. This is because a copper film electrolytically plated on a substrate has a variation of ±3-5 μm in a normal state, and accordingly, at a part having a thin plating formed thereon, has little side area for connecting a plating 7 remaining after having been etched, with the edge of the opening of a non-penetration hole 5, of which the phenomenon hardly provides the connection reliability without the metallic umbrella 6.

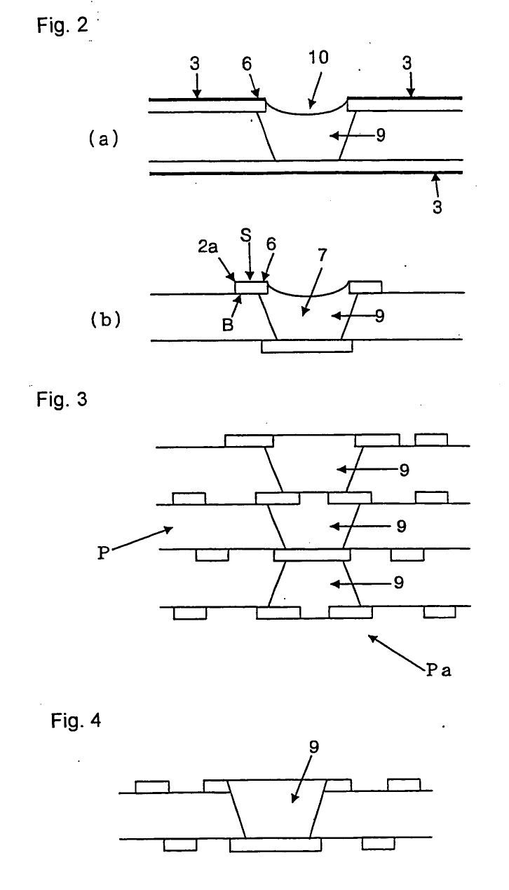

The metallic umbrella 6 is preferably left also from the viewpoint of coping with etching variation at a part 10 having no barrier metal layer formed thereon, which occurs when a plating on a barrier metal layer 3 is removed by etching, as shown in FIG. 2(a) (an expanded sectional view of a main part in FIG. 1(d)), (because the BVH can secure connection reliability even when an etched depth of a plating 7 has increased to some extent, and while FIG. 2(a) shows a case in which a plating 7 has been deeply etched).

Furthermore, a plating 7 filled in a non-penetration hole 5 is preferably formed so that the upper surface of the plating can be approximately in the same plane as the round of a BVH 9 (or equivalently “a metallic foil round 2a”), and for instance is preferably filled in a range between a back face B and an outer surface S, from the viewpoint of securing the connection reliability of the BVH and flattening the surface of an upper layer when the printed-wiring board is multi-layered (see FIG. 2(b) (an expanded sectional view of a main part in FIG. 1(f)))

The above described metallic umbrella 6 has preferably a length of 3 μm to 15 μm between the edge of the opening of a non-penetration hole 5 and the edge of the umbrella.

This is because the umbrella with the length of 3 μm or shorter hardly shows an effect for improving the connection reliability of a BVH 9, and the umbrella with the length of 15 μm or longer needs to expand the diameter of the BVH in order to keep the throwing power to the inside of the hole, which disturbs the densification of electric wiring.

Next, a barrier metal layer 3 exposed to the surface is peeled as shown in FIG. 1(e), and a metallic foil is patterned by etching to provide a printed-wiring board P shown in FIG. 1(f), in which wiring patterns 8 on both sides are connected with each other through a BVH 9.

It is the most noteworthy point that the present embodiment has a configuration of inhibiting a plating formed when forming a BVH from being formed on an external layer, while making use of a barrier metal layer.

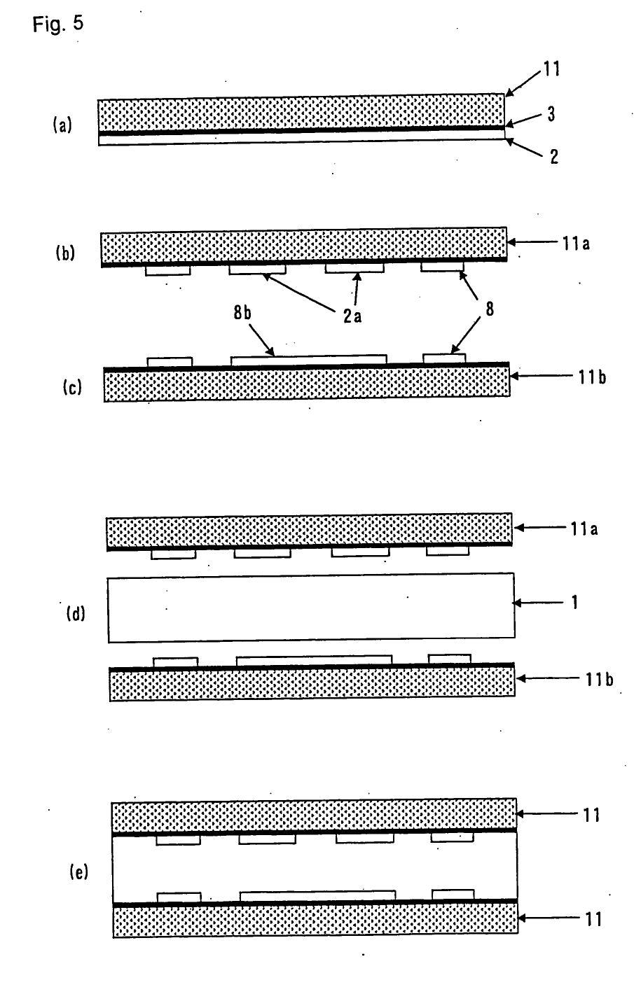

Thereby, the printed-wiring board according to the present embodiment does not need to form a plated round 8a (see FIG. 5(g)), which has been conventionally necessary; can form a metallic foil round 2a without considering an exposure accuracy which is required when forming the plated round 8a; accordingly can set the diameter of the metallic foil round 2a smaller than that by a conventional technology; and can improve the density of electric wiring. The printed-wiring board also has such a configuration as not to form a plating when forming the BVH, on the wiring pattern including the metallic foil round 2a, accordingly can flatten the surface when multi-layered, and can thin the multilayer printed-wiring board.

It is a further noteworthy point that the present embodiment can provide a configuration in which all wiring patterns including a BVH are made from copper.

Thereby, the printed-wiring board can decrease conduction resistance in comparison with a conventional technology of placing a barrier metal layer such as nickel between a BVH and a wiring pattern.

In the description of the present invention, a double-sided printed-wiring board having wiring patterns formed on both sides of an insulation layer has been taken as an example, but the configuration is not limited thereto. A multilayer printed-wiring board Pa with densified electric wiring can be also prepared, by forming a stacked via hole made by layering a plurality of the BVHs 9 of the present invention, each of which has an approximately flat surface and has a metallic foil round 2a with a small diameter, in a thickness direction (see FIG. 3).

The manufacturing process will be now briefly described below. The multilayer printed wiring board Pa with the desired number of layers can be obtained by the steps of: preparing a printed-wiring board P shown in FIG. 1(f) as a core substrate; sequentially layering a metallic foil and a barrier metal layer on both sides of the printed-wiring board P through an inter-level isolation layer; and then repeating steps shown in FIGS. 1(b) to (f). (Thereby, a fully stacked via hole can be also prepared according to the present configuration).

In addition, as described above, a metallic umbrella 6 is not always necessary for a configuration of a BVH 9, but the configuration shown in FIG. 4 can be adopted. Furthermore, it is also permitted as a matter of course to prepare a stacked via hole as shown in FIG. 3, by layering a plurality of the BVHs 9.

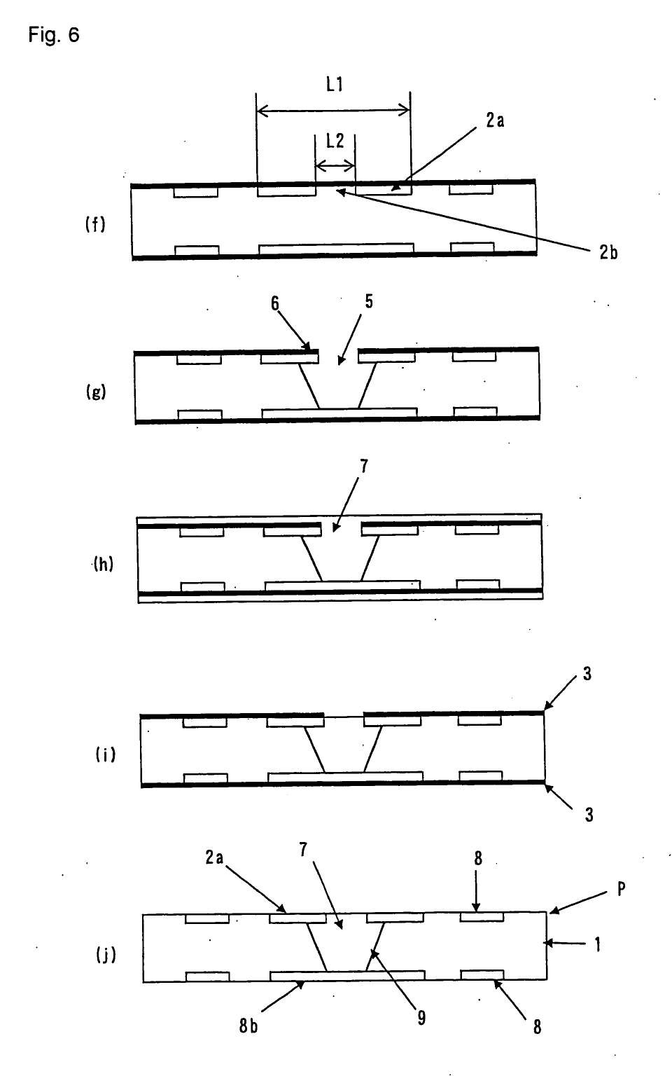

Next, other modes for carrying out the invention are described using a diagrammatic drawings for explaining production process as shown in FIGS. 5 and 6.

Firstly, as shown in FIG. 5(a), a carrier 11 (metals such as copper is used as an example in the carrier in the present figure, however, an insulation resin on which the leaving layer is formed can also be used) on which barrier metal 3 and metallic foil 2 are sequentially layered is prepared, followed by applying an etching treatment (alkali etching treatment) to the metallic foil 2. By this process a basic carrier plate 11a as shown in FIG. 5(b) having a wiring pattern 8 containing the metallic foil round 2a is obtained (similarly, a basic carrier plate 11a as shown in Fig. (e) having a wiring pattern 8 containing the via bottome round 8b is formed.)

Next, as shown in FIG. 5(d), the sides on which wiring pattern 8 is to be formed of the basic carrier plates 11a and 11b are faced to each other, and an insulation layer 1 is placed in the middle. The complex is compressed, thereby the wiring pattern 8 (containing the metallic foil round 2a and via bottom round 8b) is placed in the insulation layer 1 (FIG. 5(e).)

Next, as shown in FIG. 6(f), the basic carrier plate 11 is peeled off, and the metallic foil round 2a is irradiated with a laser beam having a diameter smaller than the diameter L1 of the metallic foil round 2a but larger than the diameter L2 of 2b, which is the opening hole of the metallic foil round 2a, thereby non-penetration hole 5 is formed so as to reach the via bottom round 8b (FIG. 6(g).)

Next, desmear treatment is applied in order to clean the non-penetration hole 5, followed by electroless-plating and electrolytical plating in this order while the metallic umbrella 6 formed by the irradiation of a laser beam is left untouched, thereby the non-penetration hole 5 is filled with the film 7 and the film 7 is exposed outside (FIG. 6(h).)

Next, as shown in FIG. 6(i), the film 7 exposed outside is removed by etching treatment (alkali etching treatment), and subsequently, the barrier metallic layer 3 exposed on the surface is peeled off, thereby the printed wiring board P as shown in FIG. 6(j) is obtained.

The noteworthy point of the mode for carrying out the present invention is that the wiring pattern 8 having the metallic foil round 2a and the via bottom round 8b is formed so that the surface of the wiring pattern is in the same plane as an insulation layer.

By applying above-described process, thickness of the printed-wiring board can be further thinned compared with the mode for carrying out the invention as described in FIG. 1.

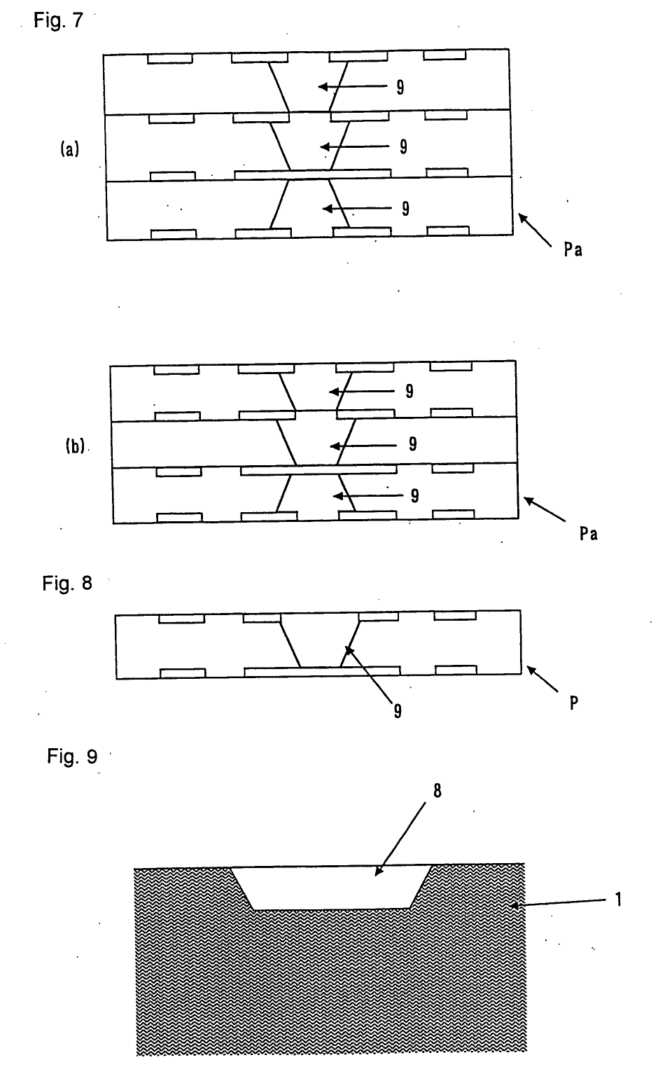

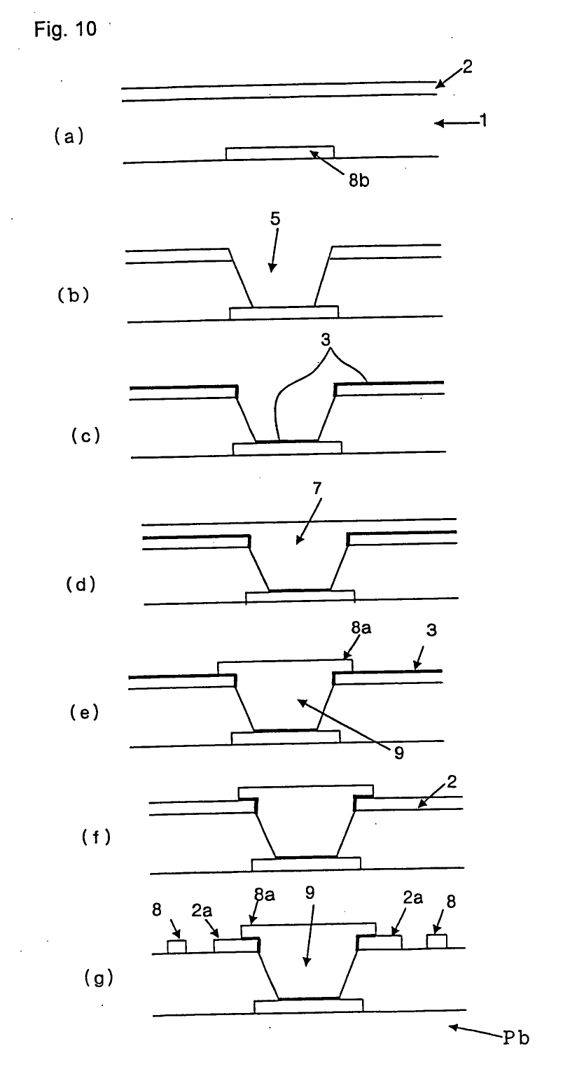

Further, it is also possible that the mode for carrying out the invention (i.e., the structure in which the wiring pattern 8 is placed so that it is in the same plane as the surface of an insulation layer 1) is multi-layered as shown in FIG. 7 similarly to FIG. 3 (FIG. 7(a) shows the multi-layered printed wiring board having the structure in which the wiring patterns of all the layers are placed in an insulation layer, and FIG. 7(b) shows the multi-layered printed wiring board having the structure in which the inner layer of the FIG. 7(a) is the printed wiring board of the FIG. 1(f)), or, as shown in FIG. 8, it can be the structure from which the metallic umbrella 6 is omitted, as similarly to FIG. 4.

In the description of the present invention, etching of a metallic foil has been taken as an example as a way to form a wiring pattern, but it is possible to form a wiring pattern by use of a film as in an additive method. Also, in the description of the present invention, formation of the barrier metallic layer was explained using an example in which it is formed in the whole area beforehand; however, it is also possible that the barrier metallic layer is formed in the whole area of an insulation layer having the wiring pattern after the wiring pattern has been placed in an insulation layer, or it can be formed in the surface of the exposed wiring pattern.

Also, as explained in the mode for carrying out the invention, formation of the wiring pattern 8 by etching creates an effective structure in terms of improvement of attachment of mechanical parts, wire bonding etc. since the exposed side becomes wide, as shown in FIG. 9.

### EXAMPLES

In the next place, the effects of densified electric wiring in and the thinning of a printed-wiring board by the present invention will be further described with reference to examples and comparative examples. The sample preparation and measurement in examples and comparative examples were carried out in the conditions described below.

At first, a sample substrate was prepared so that an average final diameter of a metallic foil round (hereafter called “a copper foil round”) can be φ 300 μm and L/S can be 30 μm/30 μm, with the use of a common wiring pattern.

Then, data was statistically collected in order to know how much location deviation of a BVH and a plated round will occur when the diameter of a copper foil round is set to φ 300 μm, and each of set values was determined for such diameters of copper foil rounds as the plated layer for the BVH does not cover the copper foil round, and as the plated layer for the BVH does not cover the perimeter of the copper foil round.

Next, a sample substrate was prepared again based on the actual data on the variations of the diameters of BVHs and each round, and the location deviations of them, to confirm what extent the diameter of each round can be minimized to.

Sample substrates of 5 lots×50 boards with a work size of 400 mm×500 mm were prepared, and the positions and diameters of a BVH, a plated round and a copper foil round were measured at 25 spots (each of 6,250 spots) per board. A length measurement microscope (QV-Apex606) made by Mitsutoyo Corporation was used for measuring the above described positions and diameters.

### Example 1

Example 1 according to the present invention will be now described with reference to FIG. 1.

At first, a dull nickel-plating with the thickness of 2 μm was formed on the copper foil of a double-sided copper laminated plate consisting of an epoxy-based insulation layer (40 μm) and copper foils with a thickness of 12 μm laminated on both sides thereof, by electrolytic nickel plating treatment (corresponding to FIG. 1(a)); and subsequently a non-penetration hole with a top diameter (an opening diameter) of φ 70 μm was prepared on a desired position (corresponding to FIG. 1(b)), by irradiation (direct irradiation on the nickel-plating) with the laser of carbon dioxide gas.

At this point, the diameter of a non-penetration hole and a location deviation were measured with a length measurement microscope. As a result, a hole diameter was φ 70 μm±3 μm and the location deviation was ±10 μm.

Next, the inside of the non-penetration hole was cleaned by desmearing treatment with the use of a permanganic-acid-based solution. (At this time, a copper umbrella formed at the opening of the non-penetration hole had a length of about 10 μm from the edge of the opening.) Then, a copper-plating was formed to fill the non-penetration hole and also was formed on the surface (of a nickel-plating) (corresponding to FIG. 1(c)), by sequentially electroless-plating copper and electrolytically plating copper on them, with the use of a plating liquid for filling a via hole.

Next, the whole area of a copper-plating formed on the nickel-plating was removed by etching with the use of an alkaline etching liquid containing a complex ammonium ion as a main component (corresponding to FIG. 1(d)); and then the nickel-plating exposed on the surface was removed with the use of a nitric-acid-based liquid for peeling a nickel film (corresponding to FIG. 1(e)).

Next, a circuit was formed in the copper foil by using a general subtractive process to obtain a printed-wiring board provided with a copper foil round of φ 300 μm and a micro wiring pattern with the L/S of 30 μm/30 μm (corresponding to FIG. 1(f)).

At this point, the diameter of a copper foil round and a location deviation were measured with a length measurement microscope. As a result, the diameter of the copper foil round was 300 μm±5 μm and the location deviation was ±20 μm.

On the basis of the above result, the possible minimum diameter of a copper foil round was calculated to prove that the diameter can be minimized to 146 μm according to the calculation, so that a sample substrate having the copper foil round with the diameter of 146 μm was actually prepared (in the same condition as in the preparation for the sample substrate having the copper foil round with the diameter of 300 μm, except that the diameter of the copper foil round was controlled to 146 μm). As a result, the printed-wiring board had no copper-plating for a BVH formed on the perimeter of the copper foil round and had the micro wiring with the L/S of 30 μm/30 μm formed thereon.

The above described possible minimum diameter of the copper foil round was determined in the following way.

Specifically, the total of variation in the diameters of a non-penetration hole (BVH) and a copper foil round and a location deviation, or equivalently, an annular ring (width of one side of the round formed around the non-penetration hole) is 3+10+5+20=38 μm, so that the diameter of the copper foil round is, diameter of non-penetration hole+2×annular ring=70+2×38=146 μm.

### Comparative Example 1

Subsequently, Comparative Example 1 will be described (of which the finished printed-wiring board has the same BVH round as in the case of FIG. 5(g) formed therein).

The printed-wiring board was prepared by the steps of: at first preparing a double-sided copper-laminated plate consisting of an epoxy-based insulation layer (40 μm) and copper foils with a thickness of 12 μm laminated on both sides thereof; increasing the absorbency of the double-sided copper-laminated plate by a laser by blackening it; and then irradiating (directly irradiating) a desired position on the copper foil with the laser beam of carbon dioxide gas, to prepare a non-penetration hole with a top diameter (an opening diameter) of 70 μm.

At this point, the diameter of a laser via hole and a location deviation were measured with a length measurement microscope, and as a result, the diameter of the non-penetration hole was φ 70 μm±3 μm and the location deviation was φ 10 μm.

Next, a circuit was formed in the copper foil by using a general subtractive process to obtain a copper foil round of φ 300 μm and a micro wiring pattern with the L/S of 30 μm/30 μm.

At this point, the diameter of a copper foil round and a location deviation were measured with a length measurement microscope, and as a result, the diameter of the copper foil round was 300 μm±5 μm and the location deviation was ±20 μm.

Next, the inside of the non-penetration hole was cleaned by desmearing treatment with the use of a permanganic-acid-based solution, and then, a copper-plating was filled in the non-penetration hole and the copper-plating (12 μm) was also formed on the surface (of a nickel-plating), by sequentially electroless-plating copper (0.5 μm), electrolytically plating nickel (2 μm) and electrolytically plating copper with the use of a plating liquid for filling a via hole, on them.

Next, a copper-plated round was formed by the steps of: forming a dry resist film with the diameter of φ 200 μm on a copper foil round through exposure and development; then removing a copper-plating exposed out of the resist film by etching treatment with the use of an alkaline etching liquid containing a complex ammonium ion as a main component; peeling the dry resist film; and then removing the nickel-plating exposed on the surface with the use of a nitric-acid-based liquid for peeling a nickel film.

At this point, the diameter of a plated round and a location deviation were measured with a length measurement microscope, and as a result, the diameter of the plated round was 200 μm±10 μm and the location deviation was ±20 μm.

On the basis of the above result, the possible minimum diameter of a copper foil round was calculated to prove that the diameter can be minimized to 266 μm from the calculated value, so that a sample substrate having the copper foil round with the diameter of 266 μm was actually prepared (in the same condition as in the preparation for the sample substrate having the copper foil round with the diameter of 300 μm, except that the diameter of the copper foil round was controlled to 266 μm). As a result, the printed-wiring board had no copper-plating for a BVH formed on the perimeter of the copper foil round and had the micro wiring with the L/S of 30 μm/30 μm formed thereon.

The above described possible minimum diameter of the copper foil round was determined in the following way.

Specifically, the total of variation in the diameters of a non-penetration hole (BVH) and a copper foil round and a location deviation, or equivalently, an annular ring (the width of one side of the round formed around the non-penetration hole) is 3+10+(10×2)+(20×2)+5+20=98 μm, so that the diameter of the copper foil round is, diameter of non-penetration hole+2×annular ring=70+2×98=266 μm.

### Comparative Example 2

Subsequently, the preparation steps for Comparative Example 2 will be now described.

Comparative Example 2 was prepared by the steps of: at first preparing a double-sided copper-laminated plate consisting of an epoxy-based insulation layer (40 μm thick) and copper foils with a thickness of 12 μm laminated on both sides thereof; subsequently forming a circuit in the copper foil by using a general subtractive process to form a copper foil round with the diameter of φ 300 μm, a window part for laser perforation with the diameter of φ 70 μm in the center thereof, and a micro wiring pattern with the L/S of 30 μm/30 μm; and subsequently irradiating the window part with the laser beam of carbon dioxide gas having the diameter larger than the diameter of the window part and smaller than the diameter of the copper foil round, to prepare a non-penetration hole with a top diameter (an opening diameter) of φ 70 μm.

At this point, the diameter of a copper foil round was measured with a length measurement microscope, and as a result, it was 300 μm±5 μm. (For information, both of variation in the diameter of a non-penetration hole and a location deviation are zero, because the diameter of the non-penetration hole and the location deviation are equal to the diameter of a window part previously formed in a circuit).

Next, the inside of the non-penetration hole was cleaned by desmearing treatment with the use of a permanganic-acid-based solution, and then, a copper-plating was filled in the non-penetration hole and the copper-plating (12 μm) was also formed on the surface (of a nickel-plating), by sequentially electroless-plating copper (0.5 μm), electrolytically plating nickel (2 μm) and electrolytically plating copper with the use of a plating liquid for filling a via hole, on them.

Next, a copper-plated round was formed by the steps of: forming a dry resist film with the diameter of φ 200 μm on a copper foil round through exposure and development; then removing a copper-plating exposed out of the resist film by etching treatment with the use of an alkaline etching liquid containing a complex ammonium ion as a main component; peeling the dry resist film; and then removing the nickel-plating exposed on the surface with the use of a nitric-acid-based liquid for peeling a nickel film.

At this point, the diameter of a plated round and a location deviation were measured with a length measurement microscope, and as a result, the diameter of the plated round was 200 μm±10 μm and the location deviation was ±20 μm.

On the basis of the above result, the possible minimum diameter of a copper foil round was calculated to prove that the diameter can be minimized to 200 μm from the calculated value, so that a sample substrate having the copper foil round with the diameter of 200 μm was actually prepared (in the same condition as in the preparation for the sample substrate having the copper foil round with the diameter of 300 μm, except that the diameter of the copper foil round was controlled to 200 μm). As a result, the printed-wiring board had no copper-plating for a via hole formed on the perimeter of the copper foil round and had the micro wiring with the L/S of 30 μm/30 μm formed thereon.

The above described possible minimum diameter of the copper foil round was determined in the following way.

Specifically, the total of variation in the diameters of a copper foil round and a location deviation, or equivalently, an annular ring (the width of one side of the round formed around the non-penetration hole) is 5+(10×2)+(20×2)=65 μm, so that the diameter of the copper foil round is, diameter of non-penetration hole+2×annular ring=70+2×65=200 □m.

As a result of Example and Comparative Examples 1 and 2, it was confirmed that a printed-wiring board according to the present invention can considerably decrease the diameter of a copper foil round and densify electric wiring thereon, in comparison with a conventional configuration. (For information, a difference of the diameter between Example 1 and Comparative Example 1 was 120 μm, and the difference between Example 1 and Comparative Example 2 was 54 μm).

### Example 2 and Comparative Examples 3 and 4

Example 2 is a six-layer printed-wiring board according to the present invention, and was prepared by buildup-layering two layers at a time on both sides of a core substrate of Example 1. Similarly, Comparative Examples 3 and 4 are six-layer printed-wiring boards of a compared sample, and were prepared by buildup-layering two layers at a time respectively on both sides of core substrates of Comparative Examples 1 and 2. The thickness was measured on each of six-layer printed-wiring boards (while the thickness means the one including solder resists formed on both sides). Here, the thickness of the insulation layer formed between upper and lower wiring patterns was set at 20 μm (the thickness of the solder resist formed on the wiring pattern of the external layer was also set at 20 μm on the wiring pattern), and the thickness of the plated round in Comparative Examples 3 and 4 was set at 10 μm.

As a result of this, a compared sample showed the thickness of about 280 μm, whereas a sample according to the present invention showed the thickness of about 220 μm, which was the thickness approximately thinned as was calculated. (According to calculation, it was anticipated that the thickness of 30 μm in total on one side and the thickness of 60 μm in total on both sides, which consists of 10 μm (20 μm in total) due to each of two built-up insulation layers formed on one side of a core substrate, and 10 μm due to a solder resist formed on a wiring pattern of an external layer; and the present example proved that the printed-wiring board can be thinned approximately as was calculated, because a plated round was not formed in each layer.)

Example 2 is a six-layer printed-wiring board according to the present invention, and was prepared by buildup-layering two layers at a time on both sides of a core substrate of Example 1. Similarly, Comparative Examples 3 and 4 are six-layer printed-wiring boards of a compared sample, and were prepared by buildup-layering two layers at a time respectively on both sides of core substrates of Comparative Examples 1 and 2. The thickness was measured on each of six-layer printed-wiring boards (while the thickness means the one including solder resists formed on both sides). Here, the thickness of the insulation layer formed between upper and lower wiring patterns was set at 20 μm (the thickness of the solder resist formed on the wiring pattern of the external layer was also set at 20 μm on the wiring pattern), and the thickness of the plated round in Comparative Examples 3 and 4 was set at 10 μm.

As a result of this, a compared sample showed the thickness of about 280 μm, whereas a sample according to the present invention showed the thickness of about 220 μm, which was the thickness approximately thinned as was calculated. (According to calculation, it was anticipated that the thickness of 30 μm in total on one side and the thickness of 60 μm in total on both sides, which consists of 10 μm (20 μm in total) due to each of two built-up insulation layers formed on one side of a core substrate, and 10 μm due to a solder resist formed on a wiring pattern of an external layer; and the present example proved that the printed-wiring board can be thinned approximately as was calculated, because a plated round was not formed in each layer.)

What is claimed is:

1. A printed-wiring board having a blind via hole connecting different wiring-pattern-formed layers with each other, wherein the blind via hole is a non-penetration hole filled with a plating, and the plating is not formed on a wiring pattern including the round of the blind via hole.

2. The printed-wiring board according to claim 1, wherein the wiring pattern including the round of the blind via hole is embedded so that the surface of the wiring pattern is in the same plane as a surface of the insulation layer.

3. The printed-wiring board according to claim 1 or 2, wherein all wiring patterns including the blind via hole are made from copper.

4. The printed-wiring board according to any one of claims 1 to 3, wherein the blind via hole is the non-penetration hole filled with a film plated in a state of leaving a metallic umbrella which protrudes at the edge of the opening of the non-penetration hole and is formed when the non-penetration hole for forming the blind via hole has been prepared.

5. The printed-wiring board according to any one of claims 1 to 3, wherein the plating is filled so that the upper surface of the plating can be approximately in the same plane as the round of a blind via hole.

6. A multilayer printed-wiring board comprising a plurality of the printed-wiring boards according to any one of claims 1 to 5 layered therein.

7. A process for manufacturing a printed-wiring board having a blind via hole connecting different wiring-pattern-formed layers with each other comprising the steps of: sequentially layering at least a metallic foil and a barrier metal layer to be differently etched from the metallic foil, on an insulation layer; drilling such a non-penetration hole as to reach a desired wiring-pattern-forming layer, by directly irradiating the barrier metal layer with a laser beam; cleaning the inside of the non-penetration hole by desmearing treatment; filling the non-penetration hole with a plating, and at the same time forming a plating on the barrier metal layer, by plating treatment; removing the plating which has been formed on the barrier metal layer and protrudes from the non-penetration hole, by etching treatment; peeling the barrier metal layer; and etching the metallic foil to form a wiring pattern.

8. The process for manufacturing the printed-wiring board according to claim 7, wherein the non-penetration hole is prepared by irradiation with the laser beam of carbon dioxide gas, and is plated in a state of leaving a metallic umbrella which has been formed at the edge of the opening of the non-penetration hole by irradiation with the laser beam of carbon dioxide gas.

9. A process for manufacturing a multilayer printed-wiring board comprising repeating the steps according to claim 7 or 8.

10. A process for manufacturing a printed-wiring board having a blind via hole connecting different wiring-pattern-formed layers with each other comprising steps of: forming a wiring pattern having the round of a blind via hole; placing the wiring pattern in such a way that it is in the same plane as an insulation layer; preparing such a non-penetration hole as to reach a desired wiring-pattern-forming layer, by irradiating the round opening-hole of the blind via hole with a laser beam; cleaning the inside of the non-penetration hole by desmearing treatment; filling the non-penetration hole with a plating, and at the same time forming a plating on the outer layer, by plating under such a condition that a barrier metal layer having an etching condition diffrenent from that of the wiring pattern is placed on the part of the surface of the wiring pattern uncovered by an insulation layer; and removing by etching the plating on the outer layer; peeling the barrier metal layer.

11. The process for manufacturing the printed-wiring board according to claim 10, wherein the non-penetration hole is prepared by irradiation with the laser beam of carbon dioxide gas, and is plated in a state of leaving a metallic umbrella which has been formed at the edge of the opening of the non-penetration hole by irradiation with the laser beam of carbon dioxide gas.

12. The process for manufacturing a multilayer printed-wiring board comprising repeating the steps according to claim 10 or 11.
